(19) United States
(12) Patent Application Publication
(10) Pub. No.: US 2013/0180454 A1
(43) Pub. Date: Jul. 18, 2013

(54) THIN FILM DEPOSITION APPARATUS

(71) Applicants: Sang-Joon Park, Yongin-si (KR); Jin-Ho Kim, Hwaseong-si (KR); Byung-Guk Son, Osan-si (KR)

(72) Inventors: Sang-Joon Park, Yongin-si (KR); Jin-Ho Kim, Hwaseong-si (KR); Byung-Guk Son, Osan-si (KR)

(73) Assignee: WONIK IPS CO., LTD., Pyeongtaek (KR)

(21) Appl. No.: 13/823,846

(22) PCT Filed: Sep. 16, 2011
(86) PCT No.: PCT/KR11/06843

§ 371 Date: Mar. 15, 2013

(30) Foreign Application Priority Data
Sep. 17, 2010 (KR) 10-2010-0091852
Sep. 17, 2010 (KR) 10-2010-0091853

(51) Int. Cl. C23C 16/455

(52) U.S. Cl. CPC C23C 16/455
USPC 118/728

(57) ABSTRACT

Provided is a thin film deposition apparatus which comprises a chamber, a susceptor, a source gas supply part, and a susceptor support. The chamber has an inner space in which a deposition process is performed. The susceptor is disposed within the chamber to directly support a plurality of substrates along a circumference of a center of a top surface or support a substrate holder on which at least one substrate is disposed. The source gas supply part supplies first and second source gases into a central portion of an upper side of the susceptor in a state where the first and second gases are separated from each other. Also, the source gas supply part respectively injects the first and second source gases separated from each other toward a circumference of the susceptor through vertically arranged source gas injection holes to supply the first and second source gases onto the substrates disposed on the susceptor. The susceptor support is configured to support a center of the susceptor from a lower side of the susceptor. Also, the susceptor support includes an additional gas supply part for injecting an additional gas introduced from the outside onto a top surface of the susceptor.

### TECHNICAL FIELD

The present invention relates to a thin film deposition apparatus used for depositing a thin film on a substrate in the process of fabrication of semiconductor.

### BACKGROUND ART

In general, thin-film fabrication methods used in the semiconductor field may include chemical vapor deposition (CVD) and physical vapor deposition (PVD). In a CVD process, a gas mixture reacts on a heated substrate surface, and thereby resulting elements are deposited on the substrate surface. CVD methods may be classified into atmospheric CVD (APCVD), low pressure CVD (LPCVD), plasma enhanced CVD (PECVD), and metal organic CVD (MOCVD) based on a type of a material used as a precursor, a pressure imposed during process, a method for transferring energy necessary for reaction, and the like.

MOCVD process is generally used for single crystal growth of nitride semiconductors for light emitting diode, to which increasing attention has been paid. MOCVD is the deposition of a metal thin film on a heated substrate by introducing a source gas onto the substrate, wherein the source gas is acquired by vaporizing an organic metal compound that is a source material in liquid form.

In a MOCVD process, an injection scheme is generally used to supply a source gas to a substrate. According to such an injection scheme, an injector at a center of a chamber introduces a source gas into a center of a top of a susceptor, and then injects the source gas in a horizontal direction to a circumference of the susceptor so as to supply the source gas to the substrates on the susceptor.

However, the source gas injected from the injector to the susceptor passes through a gas entrance region close to the injector and then flows toward a growth region in which actual deposition on the substrate is carried out. The flow of source gas becomes uniform within the gas entrance region, and the source gas at least partially decomposes. In this case, the decomposition of the source gas within the gas entrance region may cause the deposition of an unnecessary thin film on a portion of the susceptor near the gas entrance region.

In addition, the size of a chamber needs to be increased to simultaneously deposit a thin film on more number of substrates. To this end, the amount of source gas supplied to the chamber also needs to be increased, which causes an increase in a size of a gas entrance region. As a result, the amount of source gas consumed for depositing an unnecessary thin film on the gas entrance region may be increased, which may intensify a waste of source gas.

As described above, the unnecessary thin film deposited on the portion of the susceptor may be stripped off and damage the substrate during deposition process, and thus it is necessary to avoid the occurrence of such an effect. As the gas entrance region increases, the probability of an unnecessary thin film being deposited thereon increases. This may cause the reduction in a length of preventive maintenance (PM) interval.

Further, the susceptor needs to be increased in diameter to simultaneously deposit a thin film on more number of substrates. According to the aforementioned injection scheme, as the size of the susceptor increases, the deposition uniformity to the substrate decreases. To overcome such drawbacks, more amount of source gas should be used, but it may lead to the deterioration of process efficiency. Moreover, when the amount of source gas in use increases, there may occur a problem that the amount of source gas increases, which does not react on a deposition surface of the substrate and remains in particle form.

### Technical Problem

The task of the present invention is to provide a thin film deposition apparatus capable of preventing the deposition of an unnecessary thin film on a gas entrance region and a waste of source gas due to the deposition of an unnecessary thin film in a large chamber, and of increasing a preventive maintenance interval.

Another task of the present invention is to provide a thin film deposition apparatus capable of ensuring the deposition uniformity to substrates in a large susceptor, reducing the amount of source gas in use, and preventing the production of particle.

### Technical Solution

The present invention provides a thin film deposition apparatus including: a chamber having an inner space in which deposition process is performed; a susceptor disposed within the chamber and configured to directly support a plurality of substrates along a circumference of a center of a top surface or support a substrate holder on which at least one substrate is disposed; a source gas supplying unit configured to separately supply a first source gas and a second source gas, and to inject the separately supplied first and second source gases toward a circumference of the susceptor, respectively, through source gas injection openings aligned vertically to each other, in order to supply the source gases onto the substrates disposed on the susceptor; and a susceptor supporter configured to support a central portion of the susceptor from a lower side of the susceptor and comprising an extra-gas supplying unit for injecting extra gas introduced from an outside of the chamber to the top surface of the susceptor.

Additional features of the invention will be set forth in the description which follows, and in part will be apparent from the description, or may be learned by practice of the invention.

### Advantageous Effects

According to the present invention, source gases are supplied to an upper side of a susceptor such that it flows along a top surface of the susceptor, and an extra gas is supplied to the top surface of the susceptor through the susceptor supporter. Accordingly, substances decomposed from the source gases are prevented from contacting a portion of the susceptor. Therefore, the deposition of an unnecessary thin film is prevented. In addition, even when the gas entrance region increases in area due to an increasing size of the chamber, it is possible to prevent source gases from being wasted due to unnecessary thin film deposition and to reduce a preventive maintenance (PM) cycle.

According to the present invention, an extra gas is supplied from the central portion of the susceptor to the upper side of the susceptor, so that the efficient use of the source gases can be realized and the deposition uniformity to the substrate also can be ensured. In addition, a phenomenon may be prevented, in which parts of the source gases do not react on the deposition surfaces of the substrates and remain in particle form. Further, the substances decomposed from the source gases in the region near the source gas injection openings are avoided from contacting the central portion of the susceptor, and thereby the deposition of an unnecessary thin film can be prevented.

### DESCRIPTION OF DRAWINGS

The accompanying drawings, which are included to provide a further understanding of the invention and are incorporated in and constitute a part of this specification, illustrate embodiments of the invention, and together with the description serve to explain the principles of the invention.

FIG. 1 is a longitudinal sectional view of a thin film deposition apparatus according to an exemplary embodiment of the present invention.

FIG. 2 is an exploded perspective view of an example of an injection cap coupled to a susceptor supporter of an extra-gas supplying unit of FIG. 1.

FIG. 3 is an assembled view of the injection cap of FIG. 2.

FIG. 4 is an exploded perspective view of another example of an injection cap coupled to the susceptor supporter of the extra-gas supplying unit of FIG. 1.

FIG. 5 is an assembled view of the injection cap of FIG. 4.

FIG. 6 is a longitudinal sectional view of a thin film deposition apparatus according to another exemplary embodiment of the present invention.

FIG. 7 is a longitudinal sectional view of a part of a susceptor and an extra-gas supplying unit of FIG. 6.

FIG. 8 is a top view of the susceptor and the extra-gas supplying unit of FIG. 6.

FIG. 9 is a longitudinal sectional view of the extra-gas supplying unit of FIG. 6 including a gas guiding unit.

### MODE FOR INVENTION

The invention is described more fully hereinafter with reference to the accompanying drawings, in which exemplary embodiments of the invention are shown.

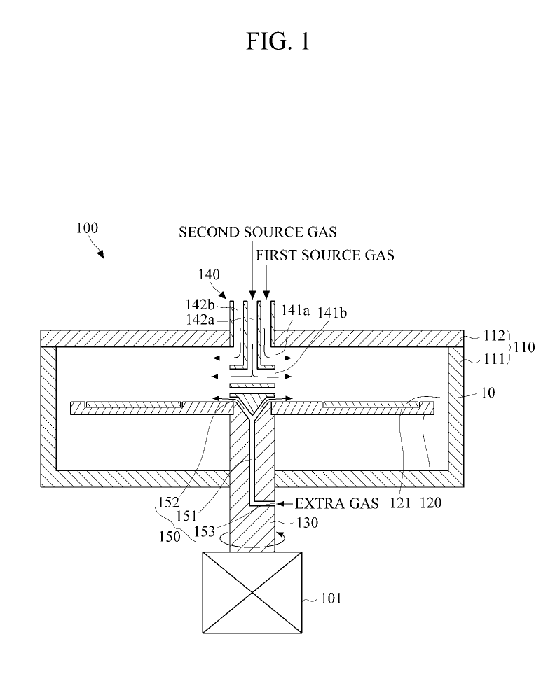

FIG. 1 is a diagram illustrating a thin film deposition apparatus.

Referring to FIG. 1, a thin film deposition apparatus 100 deposits a thin film on a substrate 10, and includes a chamber 110, a susceptor 120, a susceptor supporter 130, a source gas supplying unit 140, and an extra-gas supplying unit 150. Here, the substrate 10 may be a wafer or a glass substrate.

The chamber 110 provides an inner space in which deposition process occurs. The chamber 110 includes a chamber body 111 with an open top and a top lid 112 to cover the open top of the chamber body 111. The top lid 112 may have a bottom surface made of quartz and the like for the protection purpose. The top lid 112 may move downward to close the open top of the chamber body 111 when the deposition process is performed, and move upwards to open the open top of the chamber body 111 when the substrate 10 is loaded or unloaded.

The susceptor 120 may be disposed in the chamber 10, and support a plurality of substrates 10 arranged along a circumference of a top surface of the susceptor 120. This is to perform thin film deposition on more number of substrates 10 for mass production. The susceptor 120 may include a plurality of substrate holding portions 121 disposed at regular intervals along a circumference of the susceptor 120. The substrate holding portions 121 may stably hold and support the individual substrates 10. As another example, although not illustrated, there may be a plurality of substrate holders arranged and installed at regular intervals around the center of the susceptor 120. Each holder may hold and support at least one substrate on a top surface thereof.

The susceptor supporter 130 is configured to support a central portion of the susceptor 120 from a lower side of the susceptor 120. The susceptor supporter 130 includes the extra-gas supplying unit 150. The extra-gas supplying unit 150 injects extra gas fed from the outside toward the top surface of the susceptor 120. The extra-gas supplying unit 150 prevents unnecessary thin film deposition on a portion of the susceptor 120 corresponding to a gas entrance region.

The susceptor supporter 130 allows the susceptor 120 to rotate in response to a rotation of a rotation driving device 101. For example, the susceptor supporter 130 may have a lower portion withdrawn to the outside of the chamber 110 and connected with the rotation driving device 101, whereby the susceptor supporter 130 can rotate. The susceptor 120 rotates along with the rotation of the susceptor supporter 130.

If the substrate holders are arranged on the top surface of the susceptor 120, the individual substrate holders may be rotatably installed on a gas cushion or the like. This is to provide a source gas evenly over all substrates 10 on the susceptor 120 in the process of deposition, wherein the source gas is injected from the top middle portion of the susceptor 120. The susceptor 120 is heated by a heater (not shown) to heat the substrates 10 disposed thereon in the process of deposition.

The source gas supplying unit 140 may be separately supplied with a first source gas and a second source gas from the top middle portion of the susceptor 120, and inject the received first and second source gases toward a circumference of the susceptor 120 through source gas injection openings 141a and 141b vertically aligned to each other. As a result, it is possible to supply the first source gas and the second source gas to the substrates 10 on the susceptor 120.

The source gas supplying unit 140 may be configured to inject the first and second source gases to the top surface of the susceptor 120 in a horizontal direction parallel to the top surface. The source gas supplying unit 140 may be configured in various ways, such as being inclined downward, as long as the source gas supplying unit 140 can smoothly supply the first and second source gases to the substrates 10 on the susceptor 120.

Further, the source gas supplying unit 140 may further include feeding lines 142a and 142b to provide separately the first source gas and the second source gas. The feeding lines 142a and 142b may pass through the top lid 112, extending to the top middle portion of the susceptor 120, and be bent in such a manner that the source gas injection openings 141a and 141b formed on the extending ends of the respective feeding lines 142a and 142b are aligned vertically to each other.

More specifically, the first source gas and the second source gas injected from the source gas supplying unit 140 pass through the gas entrance region close to the source gas injection openings 141a and 141b, and flow to a growth region in which active deposition on the substrates 10 occurs. The flows of the first source gas and the second source gas are equalized in the gas entrance region and the first and second source gases at least partially decomposes and the decomposing substances tend to fall on the top surface of the susceptor 120.

At this time, the extra-gas supplying unit 150 injects an extra gas to the top surface of the susceptor 120, and the extra gas flows from the gas entrance region to the growth region. While the extra gas is flowing to the growth region, the substances decomposing from the first and second source gases are pushed by the extra gas, thereby being prevented from falling down to the top surface of the susceptor 120 and being induced to flow to the growth region.

As such, the substances decomposing from the first and second source gases are prevented from contacting a portion of the susceptor 120 corresponding to the gas entrance region, and thus unnecessary deposition of a thin film can be avoided. In addition, even when the gas entrance region increases in area due to an increasing size of the chamber 110, it is possible to prevent source gases from being wasted due to unnecessary thin film deposition and to reduce a prevention maintenance (PM) cycle.

In addition, the extra-gas supplying unit 150 may include a gas passage 151 formed inside the susceptor supporter 130 to receive the extra gas from the outside of the chamber 110, and an extra-gas injection opening 152 from which the extra gas entering through the gas passage 151 is injected toward the top surface of the susceptor 120.

The extra-gas injection opening 152 may be connected to the gas passage 151 along the side of the susceptor supporter 130. That is, an exit of the gas passage 151 may be connected to the extra-gas injection opening 152 and an entrance of the gas passage 151 may be connected to an extra-gas entering opening 153. The extra-gas entering opening 153 is placed at a portion of the susceptor supporter 130 which is withdrawn to the outside of the chamber 110. The extra-gas entering opening 153 is connected to an extra-gas supply to allow the extra gas to flow into the gas passage from the extra-gas supply.

In addition, the extra-gas injection opening 152 may be located higher than the top surface of the susceptor supporter 130 so as to inject the extra gas toward the top surface of the susceptor supporter 130. There may be a plurality of extra-gas injection opening 152 formed on the side of the susceptor supporter 130, so that the extra gas can be fed to the gas entrance region from different directions simultaneously. In another example, the extra-gas injection opening 150 may be arranged on the top surface of the susceptor supporter 130 as well as on the side of the susceptor supporter 130. The size and shape of the extra-gas injection opening 152 and the amount of gas injected from the extra-gas injection opening 152 may vary within practical limits without affecting the aforementioned functions of the extra-gas injection opening 152.

The extra gas may be injected in a direction parallel to the top surface of the susceptor 120. However, the extra gas may be injected in an upward direction at an angle relative to the top surface of the susceptor 120 without affecting the function of the extra-gas injection opening 152. For example, the direction in which the extra gas is injected may be adjusted according to an angle between the gas passage 151 and the extra-gas injection opening 152, or may be adjusted by a guide member installed at a front side of the extra-gas injection opening 152.

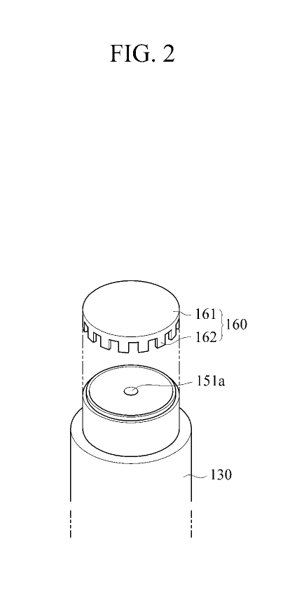

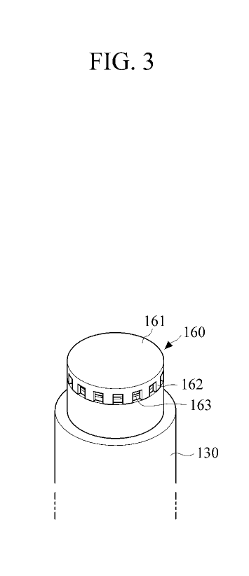

Meanwhile, as shown in FIGS. 2 and 3, an injection cap 160 may be coupled to a top of the susceptor supporter 130. The injection cap 160 may form an inner space connected to the gas passage 151. In addition, there may be a plurality of extra-gas injection openings 152 which are arranged on the side of the injection cap 160 while being connected to the inner space of the injection cap 160. For example, the injection cap 160 may consist of a disk-shaped cap body 161 and a number of ribs 162 that are arranged along the circumference of the cap body 161 and spaced apart from one another, while extending downward from the cap body 161.

The injection cap 160 may be coupled to the susceptor supporter 130 in such a manner that ends of the respective ribs 162 are fixed onto the circumference of the top of the susceptor supporter 130 while a bottom surface of the cap body 161 is spaced apart from the top of the susceptor supporter 130. As a result, a space is formed between the bottom surface of the cap body 161 and the top surface of the susceptor supporter 130, while communicating with openings 163 between the ribs 162.

The openings 163 function as the extra-gas injection openings 152. In this case, an exit of the gas-passage 151 is placed on the top surface of the susceptor supporter 130. Hence, the extra gas fed into the space between the injection cap 160 and the susceptor supporter 130 from the exit 151a of the gas passage 151 may be injected into the chamber through the openings 163 arranged along the circumference of the injection cap 160.

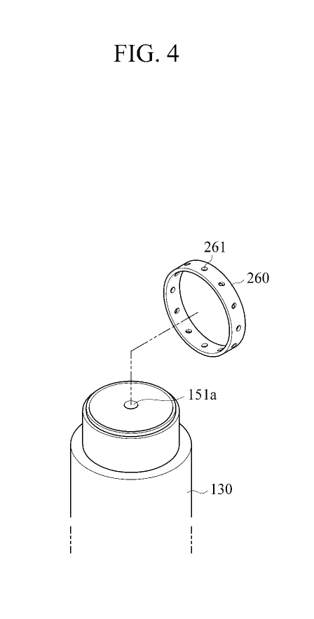

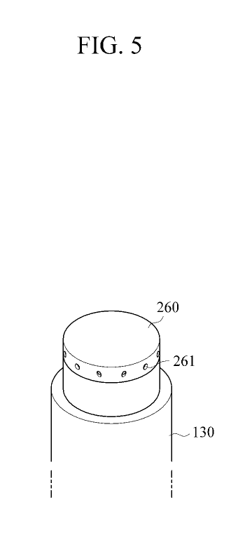

In another example, as shown in FIGS. 4 and 5, the injection cap 260 may have an inner space with an open bottom. In addition, a number of holes 261 may be arranged along the circumference of the injection cap 260 while communicating with the inner space of the injection cap 260. A bottom surface of the injection cap 260 is spaced apart from the top surface of the susceptor supporter 130. A lower part of the injection cap 260 may be fixedly coupled to the circumference of the top of the susceptor supporter 130 while the holes 261 are placed above the susceptor supporter 130.

Accordingly, the extra gas may be fed from the exit of the gas passage 151 into a space between the injection cap 260 and the susceptor supporter 130, and then injected into the chamber through the holes arranged along the circumference of the injection cap 160. That is, the holes 261 function as the extra-gas injection openings 152. In addition, the injection cap 260 may include an inner passage connected to the gas passage 151 and to each of the extra-gas injection openings 152.

When deposition process is performed using III-V-group MOCVD, the first source gas may include V-group elements, and the second source gas may include III-group elements. The first source gas, as hydride including V-group elements, may be, for example, NH₃, PH₃, AsH₃ or the like. The second source gas, as organic metal including III-group elements, may be, for example, Trimethylgallium (TMG), triethylgallium (TEG), trimethylindium (TMI), or the like. Each of the first and second source gases may include a carrier gas.

The extra gas may be at least one gas selected from a gas including V-group elements, a hydrogen gas, and an inert gas. A gas including V-group elements may be, for example, hydride, such as NH₃, PH₃, and AsH₃, which include V-group elements. An inert gas may be a N₂ gas, a He gas, or an Ar gas.

The source gas supplying unit 140 may inject the source gas including V-group elements and the source gas including III-group elements through different source gas injection openings in such a manner that the source gas including III-group elements is injected through a source gas injection opening closest to the susceptor 120. Alternatively, the source gas injection opening closest to the susceptor 120 may inject the source gas including V-group elements.

In addition, although not illustrated, the thin film deposition apparatus 100 may further include an inert gas supplying unit disposed between the source gas injection openings 141a and 141b of the source gas supplying unit 140, or either above the upper source gas injection opening 141a of the source gas supplying unit 140 or below the lower source gas injection opening 141b of the source gas supplying unit 140, in order to supply an inert gas.

The inert gas supplied from the inert gas supplying unit may prevent the reaction between the first source gas and the second source gas in an area near the source gas injection openings when they are injected from the source gas supplying unit 140, or functions as a carrier for the first and second source gases. The inert gas may be a N₂ gas, a He gas, or an Ar gas.

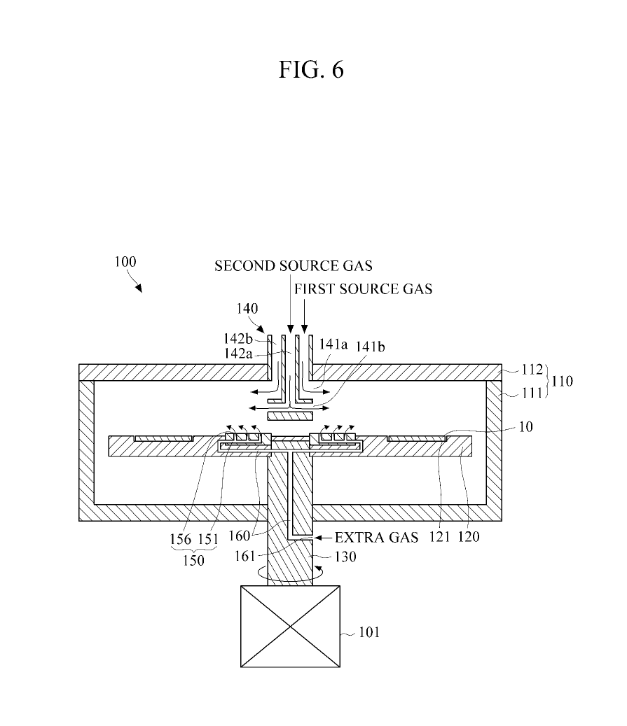

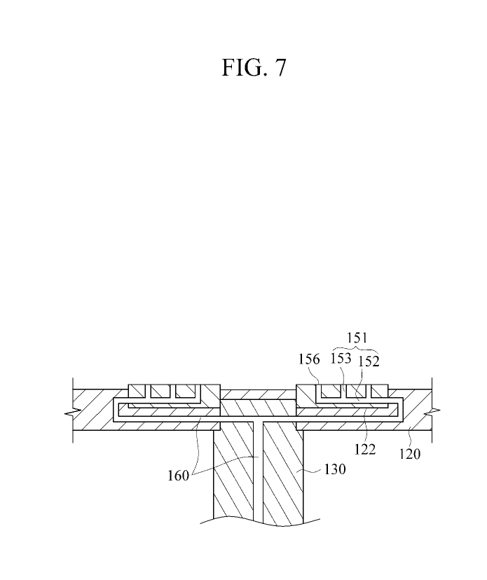

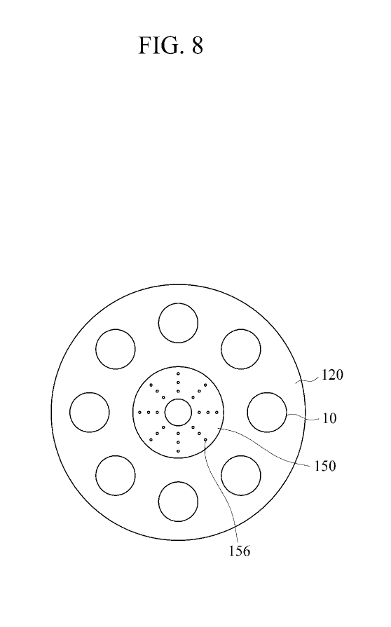

FIG. 6 is a longitudinal sectional view illustrating a thin film deposition apparatus according to anther exemplary embodiment of the present invention. FIG. 7 is a longitudinal sectional view of a part of a susceptor and an extra-gas supplying unit shown in FIG. 6. FIG. 8 is a top view of the susceptor and the extra-gas supplying unit of FIG. 6.

Referring to FIGS. 6 to 8, a thin film deposition apparatus 300 includes a chamber 310, a susceptor 320, a susceptor supporter 330, a source gas supplying unit 340, and an extra-gas supplying unit 350, in order to deposit a thin film on a substrate 10.

The chamber 310 has an inner space in which deposition process is performed. The chamber 310 includes a chamber body 311 with an open top and a top lid 312 to cover the open top of the chamber body 311. The top lid 312 may have a ceiling, made of quartz or the like, on a bottom surface for the protection purpose. The top lid 312 may move downwards, during the deposition process, to close the open top of the chamber body 311, and move upwards to open the open top of the chamber body 311 during the loading or unloading of the substrate.

The susceptor 320 is disposed inside the chamber 310, and support a plurality of substrates 10 along a circumference of its top surface of the susceptor. There may be a plurality of substrate holding portions 321 arranged at regular intervals along the circumference of the susceptor. The holding portions 321 may stably hold and support the respective substrates 10. As another example, although not illustrated, a plurality of substrate holders may be installed at regular intervals along the circumference of the susceptor 320. Each of the substrate holders may hold and support at least one substrate.

The susceptor supporter 330 is configured to support a central portion of the susceptor 320 from a lower side of the susceptor 320. The susceptor supporter 330 allows the susceptor 320 to rotate in response to the rotation of a rotation driving device 301. For example, the susceptor supporter 330 may have a lower portion withdrawn to the outside of the chamber 310 and connected with the rotation driving device, whereby the susceptor supporter 330 can rotate. The susceptor 320 rotates along with the rotation of the susceptor supporter 330.

If the substrate holders are arranged on the top surface of the susceptor 320, the individual substrate holders may be rotatably installed on a gas cushion or the like. This is to provide a source gas evenly over all substrates 10 on the susceptor 320 in the process of deposition, wherein the source gas is injected from the top middle portion of the susceptor 320. The susceptor 320 is heated by a heater (not shown) to heat the substrates 10 disposed thereon in the process of deposition.

The source gas supplying unit 340 may be separately supplied with a first source gas and a second source gas from the top middle portion of the susceptor 320, and inject the received first and second source gases toward a circumference of the susceptor 320 through source gas injection openings 341a and 341b vertically aligned to each other. As a result, it is possible to supply the first source gas and the second source gas to the substrates 10 on the susceptor 320.

The source gas supplying unit 340 may be configured to inject the first and second source gases to the top surface of the susceptor 320 in a horizontal direction parallel to the top surface. The source gas supplying unit 340 may be configured in various ways, such as being inclined downward, as long as the source gas supplying unit 140 can smoothly supply the first and second source gases to the substrates 10 on the susceptor 320.

Further, the source gas supplying unit 340 may further include feeding lines 342a and 342b to provide separately the first source gas and the second source gas. The feeding lines 342a and 342b may pass through the top lid 312, extending to the top middle portion of the susceptor 320, and be bent in such a manner that the source gas injection openings 341a and 341b formed on the extending ends of the respective feeding lines 342a and 342b are aligned vertically to each other.

The extra-gas supplying unit 350 is installed at a central portion of the top surface of the susceptor, which is inner than a substrate-holding portion of the susceptor 320 that supports the substrates, and provides the extra gas to the upper side of the susceptor 320. The extra-gas supplying unit 350 includes a gas passage unit 351 through which the extra gas is fed from the outside of the chamber 310 and an extra-gas injection opening 356 from which the extra gas fed through the gas passage unit 351 is injected to the top surface of the susceptor 320. The gas passage unit 351 is disposed inside the extra-gas supplying unit 350, and the extra-gas injection opening 356 is arranged on a top surface of the extra-gas supplying unit 350 while being connected to the gas passage unit 351.

Even when the susceptor 320 increases in diameter, the extra-gas supplying unit 350 enables efficient use of the first and second source gases and also improves deposition uniformity on the substrates 10. More specifically, the first and the second source gases, injected from the source gas supplying unit 340, flow toward the circumference of the susceptor 320. The first and second source gases flowing toward the circumference of the susceptor 320 are supplied to a deposition surface of each substrate 10 and react with the deposition surface, and thereby a thin film is formed thereon. However, on a larger susceptor 320 with an increased diameter, the first and second source gases may not be uniformly supplied onto the entire deposition surfaces of the substrates 10, and therefore the deposition uniformity on the substrates 10 may be deteriorated unless the amount of the first and second source gases in use is increased.

However, the extra gas is supplied to the upper side of the susceptor 320 from the extra-gas supplying unit 350 and flows toward the circumference of the susceptor 320. Such flow of the extra gas makes the first and second source gases to flow further to the circumference of the susceptor 320. The supply of the extra gas from the extra-gas supplying unit 350 in an effort to deliver the first and second sources gases uniformly over the entire deposition surfaces of the substrate 10 may enable the efficient use of the first and second source gases and, at the same time, ensure the deposition uniformity to the substrates 10. In addition, a phenomenon may be prevented, in which parts of the source gases do not react on the deposition surfaces of the substrates and remain in particle form.

In addition, the extra-gas supplying unit 350 is positioned at the central portion of the susceptor 320, which is inner than the substrate holding portion of the top surface of the susceptor 320, and supplies the extra gas to the upper portion of the susceptor 320. Thus, substances decomposed from the first and second source gases are prevented from moving downward from the area near the source gas injection openings 341a and 341b to the central portion and, instead, are led to the substrate holding portion. Thus, the substances decomposed from the first and second source gases are avoided from contacting the central portion of the susceptor 320, and thereby the deposition of an unnecessary thin film is prevented.

In addition, as shown in FIG. 7, a plurality of extra-gas injection opening 356 may be arranged radially or concentrically in an effort to supply the extra gas to the upper portion of the susceptor 320 from different directions. Here, the extra-gas injection openings 356 may be aligned radially or concentrically at a regular angle to each other in order to inject the extra gas evenly over the entire top surface of the susceptor 320. In this case, the gas passage unit 351 may include a main passage 352 and branch passages 353 which branch off from the main passage and are connected to the respective extra-gas injection openings 356. The extra gas fed into the main passage 352 may be separately transferred into the branch passages 353 and then injected through the extra-gas injection openings 356.

The extra-gas supplying unit 350 is partially placed in an accommodating groove 322 of the susceptor 320 in such a manner that the extra-gas injection openings 356 can be placed higher than the substrates 10 on the susceptor 320. Here, the extra-gas supplying unit 350 may be fixed to the susceptor 320 in contact or non-contact with a bottom of the accommodating groove 322. The extra-gas supplying unit 350 may be made of graphite coated with SiC, BN. Alternatively, the extra-gas supplying unit 350 may be made of quartz or Al₂O₃.

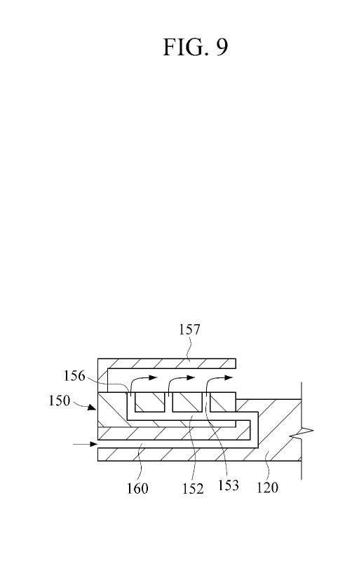

As shown in FIG. 9, the extra-gas supplying unit 350 may include a gas guiding unit 357 to guide the extra gas injected from the extra-gas injection openings 356 to flow in a direction parallel to the top surface of the susceptor 320 and toward the circumference of the susceptor 320. The gas guiding unit 357 may guide the flow of the extra gas injected from the extra-gas injection openings 356 to move in an upward direction at an angle relative to the top surface of the susceptor 320, or the extra-gas injection openings 356 may be aligned in such a manner to inject the extra gas in an upward direction at an angle relative to the top surface of the susceptor 320.

The thin film deposition apparatus 300 may further include an extra-gas supplying passage 360. The extra-gas supplying passage 360 is formed inside the susceptor supporter 330. The extra-gas supplying passage 360 receives the extra gas from the outside of the chamber 310 and transfers it to the gas passage unit 351. One end of the extra-gas supplying passage 360 extends inside the susceptor 320 and is connected to the main passage 352 of the gas passage unit 351, and the other end is connected to an extra-gas entering opening 361 of the susceptor supporter 330. The extra-gas entering opening 361 is placed at a portion withdrawn from the susceptor supporter 330 to the outside of the chamber 310. The extra-gas entering opening 361 is connected to the external extra-gas supply, allowing the extra gas to be fed into the extra-gas supplying passage 360 from the extra-gas supply.

Meanwhile, deposition process is performed using III-V-group MOCVD, the first source gas may include V-group elements, and the second source gas may include III-group elements. The first source gas, as hydride including V-group elements, may be, for example, NH₃, PH₃, AsH₃ or the like. The second source gas, as organic metal including III-group elements, may be, for example, Trimethylgallium (TMG), triethylgallium (TEG), trimethylindium (TMI), or the like. Each of the first and second source gases may include a carrier gas.

The extra gas may be at least one gas selected from a gas including V-group elements, a hydrogen gas, and an inert gas. A gas including V-group elements may be, for example, hydride, such as NH₃, PH₃, and AsH₃, which include V-group elements. An inert gas may be a N₂ gas, a He gas, or an Ar gas.

The source gas supplying unit 340 may inject the source gas including V-group elements and the source gas including III-group elements through different source gas injection openings in such a manner that the source gas including III-group elements is injected through a source gas injection opening closest to the susceptor 320. Alternatively, the source gas injection opening closest to the susceptor 320 may inject the source gas including V-group elements.

In addition, although not illustrated, the thin film deposition apparatus 300 may further include an inert gas supplying unit disposed between the source gas injection openings 341a and 341b of the source gas supplying unit 340, or either above the upper source gas injection opening 341a of the source gas supplying unit 340 or below the lower source gas injection opening 341b of the source gas supplying unit 340, in order to supply an inert gas.

The inert gas supplied from the inert gas supplying unit may prevent the reaction between the first source gas and the second source gas in an area near the source gas injection openings when they are injected from the source gas supplying unit 140, or functions as a carrier for the first and second source gases. The inert gas may be a N₂ gas, a He gas, or an Ar gas.

It will be apparent to those skilled in the art that various modifications and variation can be made in the present invention without departing from the spirit or scope of the invention. Thus, it is intended that the present invention cover the modifications and variations of this invention provided they come within the scope of the appended claims and their equivalents.

1. A thin film deposition apparatus comprising:
a chamber having an inner space in which deposition process is performed;
a susceptor disposed within the chamber and configured to directly support a plurality of substrates along a circumference of a center of a top surface or support a substrate holder on which at least one substrate is disposed;
a source gas supplying unit configured to separately supply a first source gas and a second source gas, and to inject the separately supplied first and second source gases toward a circumference of the susceptor, respectively, through source gas injection openings aligned vertically to each other, in order to supply the source gases onto the substrates disposed on the susceptor; and
a susceptor supporter configured to support a central portion of the susceptor from a lower side of the susceptor and comprising an extra-gas supplying unit for injecting extra gas introduced from an outside of the chamber to the top surface of the susceptor.

2. The thin film deposition apparatus of claim 1, wherein the extra gas is at least one gas selected from a gas including V-group elements, a hydrogen gas and an inert gas.

3. The thin film deposition apparatus of claim 2, wherein the first source gas includes V-group elements and the second source gas includes III-group elements.

4. The thin film deposition apparatus of claim 3, wherein the source gas supplying unit injects the source gas including V-group elements and the source gas including III-group elements through different source gas injection openings in such a manner that the source gas including III-group elements is injected through a source gas injection opening closest to the susceptor.

5. The thin film deposition apparatus of claim 1, wherein the extra-gas supplying unit comprises a gas passage which is formed inside the susceptor supporter to allow the extra gas to be fed from the outside of the chamber, and an extra-gas injection opening through which the extra gas fed through the gas passage is injected to the top surface of the susceptor.

6. The thin film deposition apparatus of claim 5, wherein there are a plurality of extra-gas injection openings arranged on a side of the susceptor supporter while being connected to the gas passage, or there are a plurality of extra-gas injection openings arranged on both the side and a top surface of the susceptor supporter while being connected to the gas passage.

7. The thin film deposition apparatus of claim 5, wherein a top of the susceptor supporter is coupled with an injection cap having an inner space or an inner passage that is connected to the gas passage, and there are a plurality of the extra-gas injection openings arranged on a side of the injection cap while being connected to the inner space or the inner passage of the injection cap, or there are a plurality of the extra gas injection openings arranged on both the side and a top surface of the injection cap while being connected to the inner space or the inner passage of the injection cap.

8. The thin film deposition apparatus of claim 5, wherein the extra gas is injected in a direction parallel to the top surface of the susceptor or in an upward direction at an angle relative to the top surface of the susceptor.

9. The thin film deposition apparatus of claim 1, further comprising:
an inert gas supplying unit disposed either above an upper source gas injection opening of the source gas supplying unit or below a lower source gas injection opening of the source gas supplying unit, or disposed between the source gas supplying units, in order to supply an inert gas.

10. The thin film deposition apparatus of claim 5, wherein there are a plurality of extra-gas injection openings radially or concentrically.

11. The thin film deposition apparatus of claim 5, wherein the extra-gas supplying unit comprises a gas guiding unit configured to guide the extra gas injected from the extra-gas injection openings to flow in a direction parallel to the top surface of the susceptor and toward the circumference of the susceptor.

12. The thin film deposition apparatus of claim 5, further comprising:
an extra-gas supplying passage formed in the susceptor supporter to allow the extra gas fed from the outside of the chamber to transferred therethrough to a gas passage unit of the extra-gas supplying unit.

13. The thin film deposition apparatus of claim 5, further comprising:
an inert gas supplying unit configured disposed either above an upper source gas injection opening of the source gas supplying unit or below a lower source gas injection opening of the source gas supplying unit, or disposed between the source gas supplying units, in order to supply an inert gas.
